(19) United States
(12) Patent Application Publication
(10) Pub. No.: US 2008/0104460 A1
(43) Pub. Date: May 1, 2008

(54) Medium defect detector and information reproducing device

(75) Inventor: Toshikazu Kanaoka, Kawasaki (JP)

Correspondence Address: GREER, BURNS & CRAIN, 300 S WACKER DR, 25TH FLOOR, CHICAGO, IL, 60606, US

(73) Assignee: Fujitsu Limited, Kawasaki-shi (JP)

(21) Appl. No.: 11/981,175

(22) Filed: Oct. 31, 2007

(30) Foreign Application Priority Data
Oct. 31, 2006 (JP) 2006-295379

(51) Int. Cl. G11C 29/00; G06F 11/00

(52) U.S. Cl. 714/721; 714/E11.005

(57) ABSTRACT

A reproducing device performs error correction, detects a medium defect at an early stage and performs erasure correction. A reproducing device having an error correction circuit is provided with a medium defect detector. The medium defect detector computes a moving average value of the reproducing signal, slices this moving average value with a threshold Th, and detects a defect. A continuous amplitude drop can be detected accurately compared with a simple threshold detection, and deterioration of error correction capability due to a detection error can be suppressed. Also a defect can be detected in a previous stage of the error correction decoding, so a defect can be detected at an early stage, and erasure can be corrected at an early stage during error correction.

### CROSS-REFERENCE TO RELATED APPLICATIONS

This application is based upon and claims the benefit of priority from the prior Japanese Patent Application No. 2006-295379, filed on Oct. 31, 2006, the entire contents of which are incorporated herein by reference.

### BACKGROUND OF THE INVENTION

1. Field of the Invention

The present invention relates to a medium defect detector and an information reproducing device for detecting the defect portion in signals read from a medium and correcting errors, and more particularly to a medium defect detector and an information reproducing device for detecting medium defects to be a cause of a burst error in read signals and correcting errors.

2. Description of the Related Art

Errors which occur in a storage medium, such as a magnetic disk, are roughly divided into random errors and burst errors. Random errors are errors which are not long continuous, and are distributed over a wide range. Whereas burst errors are continuous errors which are generated by a defect in the medium and thermal asperity (TA), which is unique to hard disk drives.

FIG. 16 is a diagram depicting a conventional detection method for burst error caused by thermal asperity, and FIG. 17 is a block diagram depicting a PRML type reproducing device using the thermal asperity detection in FIG. 16. As FIG. 16 shows, for a burst error caused by TA which is generated by a magnetic head contacting the medium, the signal amplitude (output) of the magnetic head is binarized using the thresholds Th and −Th, and a erasure flag is generated.

As FIG. 17 shows, in a reproducing device, a reproducing waveform regenerated from the recording medium via a head passes through an amplitude variable amplifier 600 and an analog filter 610, and is input to an analog/digital converter (A/D converter) 620. The A/D converter 620 performs digital sampling according to a sampling clock. The digitally sampled waveform passes through the digital filter 630, and is equalized to a desired partial response (PR), and a PR equalized series is acquired.

For the reproducing waveform, on the other hand, the TA portion is detected by the threshold detection in the thermal asperity detector 608, as shown in FIG. 16, and the erasure symbol flag is output. At this time, the output of an amplitude variable amplifier 600 is saturated.

The PR equalized series, after waveform equalization, receives maximum likelihood decoding (ML) in a maximum likelihood decoder 604, such as a viterbi decoder, and a decoded data string is input to the error correction unit 606. The error correction unit 606 specifies an error position using an error correction code of the decoded data string, and corrects the data at the specified position in the decoded data string.

Here the erasure symbol flag from the TA decoder 608 indicates a position (symbol) where the thermal asperity was generated in the decoded data string, so the error correction unit 606 judges that an error exists in this position (symbol), and corrects the data in this position. This is called “erasure correction”.

The error correction code generally used for a hard disk is the Reed-Solomon (RS) code. With this code, an error can be corrected with a correction capability that is double the normal ability in erasure correction when an error position is known. By using the correction function of the RS code, the correction capability can be exhibited at the maximum.

A medium defect, on the other hand, is generated by a magnetic failure, scratches and dust on the medium, which primarily drops the signal amplitude. In the case of a hard disk drive, the reproducing signals become multi-level due to inter-symbol interference because high density recording/reproducing is performed. Therefore partial response equalization reproducing, which is a technology for controlling inter-symbol interference and equalizing the signals to a known level, is used.

For example, in a three-value judgment (+1, 0 and −1) of PR-4, shown in FIG. 18, it is difficult to detect whether the signal level is a signal level due to inter-symbol interference (level “0” in FIG. 18) or due to a drop in amplitude because of a medium defect (level which should be “±1 dropped to level “0”) if the simple threshold detection in FIG. 16 is used. Therefore the error correction unit 606 cannot handle the medium defect as a erasure, but corrects it as a random error.

On the other hand, a iterative decoding system, such as a turbo code and a low density parity check (LDPC) code which propagates reliability, is under consideration as a next generation signal processing technology. As FIG. 19 shows, the iterative decoding system has a plurality of decoders (e.g. a soft-input soft-output (SISO) decoder 642 for a PR channel, and a belief propagation (BP) decoder 644 for low density parity check code) as decoders 640, and errors are corrected by mutually propagating the reliability information (also called “likelihood information”) “0” and “1”.

In other words, as FIG. 19 shows, a reproducing waveform reproduced from the recording medium via a head receives a known inter-symbol interference from a waveform equalizer 602. A first decoder (SISO decoder) 642 for a PR channel outputs a most likely reliability information corresponding to “0” or “1” of recorded data.

Then based on the checked information (e.g. parity bit) added to the recorded data, a second decoder (BP decoder) 644 performs an error check, and updates the reliability information. The updated reliability information is then fed back to the first decoder 642. This iterative operation is performed under predetermined conditions, and finally the reliability information is judged as binary data “0” and “1”, and decoding completes.

The major characteristic of the iterative decoding system is that erred information of related codes, which are acquired from large blocks and random, can be corrected by a plurality of correct information at a distance position, based on the propagation of reliability information. A iterative decoding system has a very high capacity to correct the randomly distributed information by the reliability propagation.

However if a burst error occurs in the recording device due to a drop in signal amplitude, which is generated by a medium defect, incorrect reliability information is randomly dispersed and propagated, which spreads erred information and makes decoding impossible.

A method for detecting a medium defect using the characteristic of iterative decoding has been proposed (e.g. Japanese Patent Application Laid-Open No. 2003-068024). According to this method, a defective location is specified by a temporary judgment value (a value acquired by converting the reliability information into binary information using a threshold) of the SISO decoder 642 for a PR channel, and a run length limited (RLL) encoding technique provided in advance at encoding, and a erasure flag is generated.

In other words, the temporary judgment value becomes a continuation of “1” or “0” at a defective section and continuous numbers of “1s,” and “0s” are limited by an RLL, so a violation of restriction is judged by this information, and it is handled as a defect. With this technology, however, the PR channel must have a differential characteristic.

In this way, it is difficult to detect a defective section based on the PR channel reproducing signals using a simple threshold. Therefore if a PRML system is used, a burst error is generated only at a position corresponding to the defect when a defect is generated.

A iterative decoding system has a very high error correction capability for randomly dispersed information by using reliability propagation, and if the above mentioned run length limited (RLL) encoding technique is used, a erasure flag can be generated for a medium defect. With a iterative decoding system, however, a medium defect is detected based on the decoding result, so a medium defect cannot be detected in the early stages, and a detection delay occurs.

If MTR (Maximum Transition Run) code is used, a rate of “10” that can be used continually is limited, and the decoder does not output a value which violates restriction, so defect detection is impossible.

Also in the case of a perpendicular magnetic recording system, the reproducing signal has a DC component, and in a PR system having a DC component corresponding to this, the above mentioned temporary judgment value becomes a repeat of “10”. If MTR (Maximum Transition Run) code is used, a rate of “10” that can be used continually is limited, and the decoder does not output a value which violates the restriction. Therefore in the perpendicular magnetic recording system, defect detection is difficult.

### SUMMARY OF THE INVENTION

With the foregoing in view, it is an object of the present invention to provide a medium defect detector and an information reproducing device for detecting a medium defect without delay, and improving the correction performance in PR type reproducing.

It is another object: of the present invention to provide a medium defect detector and an information reproducing device for detecting a medium defect, and improving the correction performance even if MTR code is used in PR type reproducing.

It is still another object of the present invention to provide a medium defect detector and an information reproducing device for detecting a medium defect, and improving the correction performance in a perpendicular magnetic reproducing type PR reproducing.

To achieve these objects, a medium defect decoder has: a moving average computing section for computing a moving average value of an equalization signal read from a medium in a predetermined range for upper and lower equalization signals of which center is a central value of the signal amplitude; a erasure position detection section for detecting an amplitude drop position by comparing the moving average computing result and a predetermined threshold; and a conversion section for converting the detected erasure position into a signal to be reflected to the erasure error correction of the information.

An information reproducing device of the present invention has: an equalizer/decoder for waveform-equalizing and decoding a signal reproduced from the medium; an error correction circuit for correcting an error of the decoded data; a moving average computing section for computing a moving average value of the reproduced equalization signal in a predetermined range for upper and lower equalization signals of which center is a central value of the signal amplitude; a erasure position detection section for detecting an amplitude drop position by comparing the moving average computing result and a predetermined threshold; and a conversion section for converting the detected erasure position into a signal to be reflected to the erasure error correction of the error correction circuit.

In the present invention, it is preferable that the erasure position detection section has a temporary erasure flag generation section for comparing the moving average computing result and a predetermined threshold and generating temporary erasure flags, and a erasure flag generation section for integrating and deleting temporary erasure flags based on a space and a width of the temporary flag so as to generate erasure flags, and the conversion section has an error correction symbol conversion section for converting the erasure flag into a symbol of a correction unit of the error correction.

In the present invention, it is also preferable that the moving average computing section has an absolute value computing section for computing an absolute value acquired by reflecting the equalization signal with the central value of the signal amplitude as a center, and a moving average computing section for computing a moving average in a predetermined range for the computed absolute value.

In the present invention, it is also preferable that the moving average computing section separates the equalization signal into an upper equalization signal and a lower equalization signal with the central value of the signal amplitude as a center, computes a moving average in a predetermined range for the upper equalization signal and lower equalization signal respectively, and creates an upper moving average signal and a lower moving average signal, and the erasure position detection section compares the upper moving average signal and the lower moving average signal with a predetermined upper threshold and a lower threshold, and detects the amplitude drop position.

In the present invention, it is also preferable that the erasure flag generation section generates erasure flags by integrating temporary erasure flags based on the space of the temporary erasure flags, and deleting the temporary erasure flags based on the width of the temporary erasure flag.

In the present invention, it is also preferable that the equalization signal is a PR (Partial Response) equalization signal.

In the present invention, it is also preferable that the conversion section further has a block conversion section for converting the detected erasure position into an information block of a modulation block of the reproducing signal, and a symbol conversion section for converting the converted erasure position into a symbol unit to be reflected to the erasure error correction.

In the present invention, it is also preferable that when the reproducing signal is an unsystematic code modulation signal, the block conversion section converts the detected erasure position into an information block unit of the modulation block of the reproducing signal.

In the present invention, it is also preferable that the block conversion section associates the detected position with each bit of the information block of the modulation block of the reproducing signal when the reproducing signal is a systematic code modulation signal.

In the present invention, it is also preferable that the threshold is determined from an average value of the amplitudes of the equalization signal.

Since the moving average value of the reproducing signal is computed, and this moving average value is sliced with a threshold to detect a medium defect section, a continuous amplitude drop can be detected accurately compared with a sample threshold detection, and the deterioration of error correction capability, due to a detection error, can be suppressed, and in particular a medium defect section can be detected from a reproducing signal even if it is a multi-value PR reproducing signal. Also a defect can be detected in the previous stage of the error correction decoding, so a defect can be detected at an early stage, and by performing erasure error correction in an error correction decoder, error correction capability can be made efficient, and data reliability can be improved. Even in a perpendicular magnetic recording system of which reproducing signals have a DC component, a medium defect can be detected, therefore the present invention can contribute to improving the decoding performance.

### BRIEF DESCRIPTION OF THE DRAWINGS

FIG. 1 is a block diagram depicting a first embodiment of the recording/reproducing device of the present invention;

FIG. 2 is a diagram depicting the medium defect detection operation of the medium defect detector in FIG. 1;

FIG. 3 is a block diagram depicting a recording system according to the second embodiment of the recording/reproducing device of the present invention;

FIG. 4 is a block diagram depicting a reproducing system according to the second embodiment of the recording/reproducing device of the present invention;

FIG. 5 is a block diagram depicting a first embodiment of the medium defect detector in FIG. 1;

FIG. 6 is a diagram depicting the medium defect detection operation in FIG. 5;

FIG. 7 is a diagram depicting the threshold in FIG. 5 and FIG. 6;

FIG. 8 is a diagram depicting the threshold setting in FIG. 5 and FIG. 6;

FIG. 9 is a block diagram depicting the erasure flag generation section in FIG. 5;

FIG. 10 is a diagram depicting the operation of the erasure flag generation section in FIG. 9;

FIG. 11 is a diagram depicting the operation of the unsystematic code of the modulated code block conversion section in FIG. 5;

FIG. 12 is a diagram depicting the operation of systematic code of the modulated code block conversion section in FIG. 5;

FIG. 13 is a diagram depicting the operation of the error correction symbol conversion section in FIG. 5;

FIG. 14 is a block diagram depicting a second embodiment of the medium defect detector in FIG. 1;

FIG. 15 is a diagram depicting the medium defect detection operation in FIG. 14;

FIG. 16 is a diagram depicting a conventional thermal asperity detection operation;

FIG. 17 is a block diagram depicting a conventional PRML type reproducing device;

FIG. 18 is a diagram depicting a conventional PR equalization output when a defect occurs; and

FIG. 19 is a block diagram depicting a conventional iterative decoding system.

### DESCRIPTION OF THE PREFERRED EMBODIMENTS

Embodiments of the present invention will now be described in the sequence of first embodiment of recording/reproducing device, second embodiment of recording/reproducing device, medium defect detector, and other embodiments, but the present invention is not limited to these embodiments.

### First Embodiment of Recording/Reproducing Device

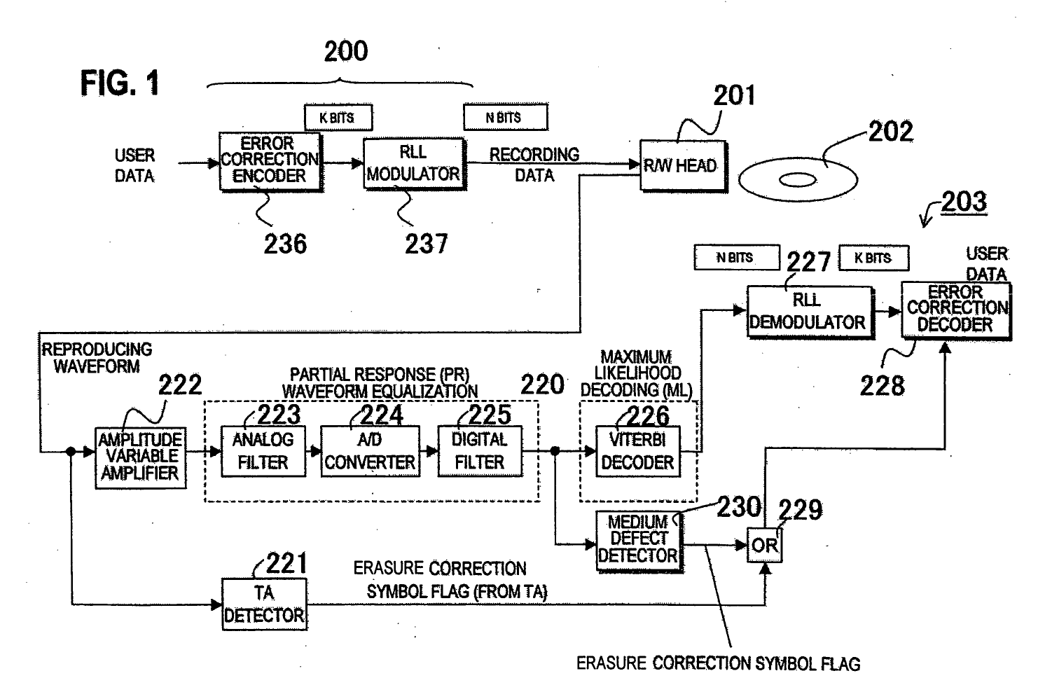

FIG. 1 is a block diagram depicting a first embodiment of the recording/reproducing device of the present invention, and shows a PRML recording/reproducing device of a magnetic disk device. As FIG. 1 shows, the recording/reproducing system of the magnetic disk device is mainly comprised of a recording circuit 200, a read/write head 201, a magnetic disk 202 and a reproducing circuit 203.

For recording, an error correction encoder 236 creates and adds an error correction code to the user data. For the error correction encoder 236, an ECC (Error Correction Code) encoder, for example, is used. Then an RLL converter (recording encoder) 237 converts the data into a data string (recording data string) where constraint conditions, such as RLL (Run Length Limited) code, are satisfied.

By the recording data string, a preamplifier, which is not illustrated, generates a write current by a write head of a read/write head 201, drives the write head, and records the data on a magnetic disk 202.

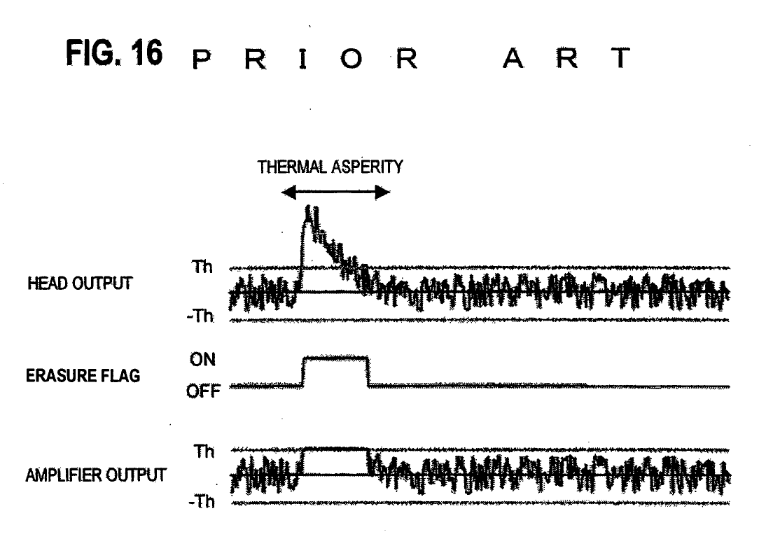

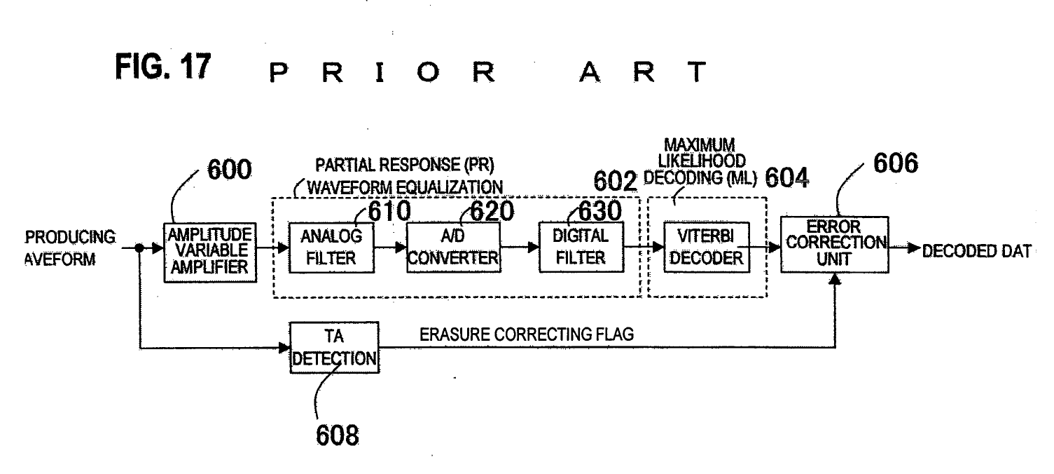

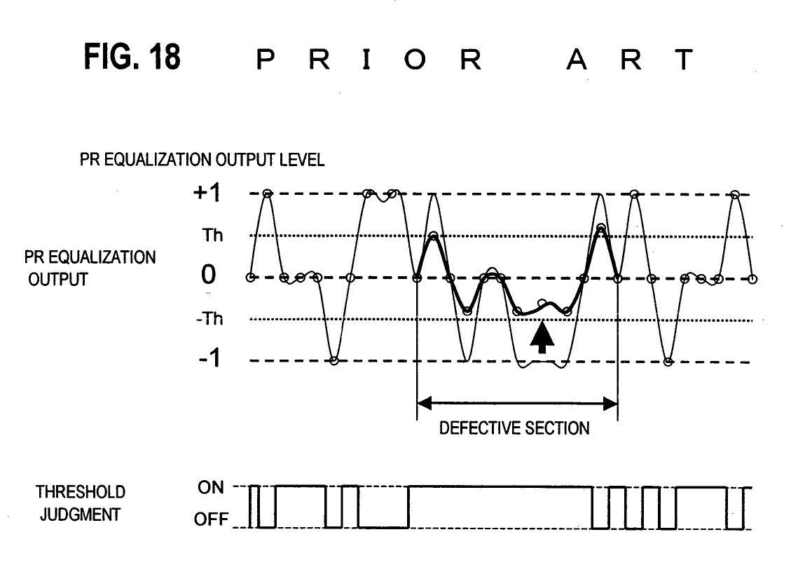

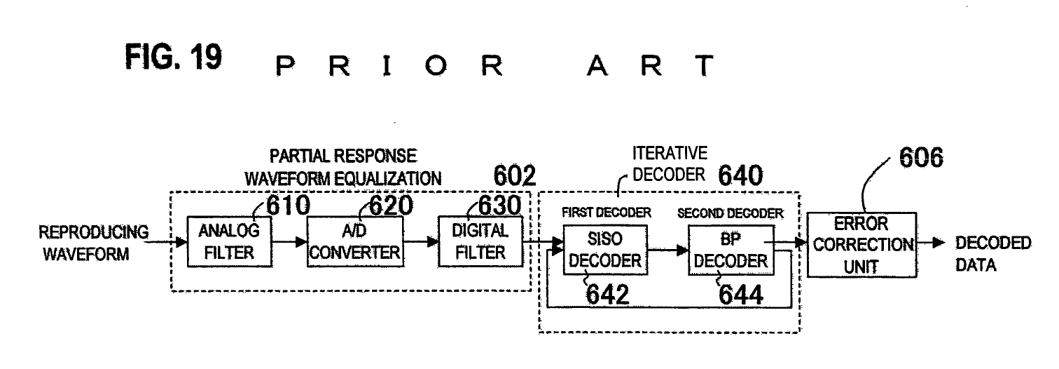

For reproducing, a read head of the read/write head 201 reads the recorded data from the magnetic disk 202. A reproducing waveform from the read head is input to a preamplifier, which is not illustrated. A thermal asperity detector 221, as described in FIG. 16, detects thermal asperity from the reproducing waveform. If thermal asperity is detected, the thermal asperity detector 221 outputs a erasure correction symbol flag for this portion.

A variable gain amplifier (VGA) 222 adjusts the amplitude of the reproducing waveform, and outputs it to a PR waveform equalization section 220. In the PR waveform equalization section 220, an analog (low pass) filter (LPF) 223 cuts a high frequency band of the reproducing signal of which amplitude has been adjusted, and an A/D converter (ADC) 224 converts the analog output thereof into digital signals. Then a digital filter 225, such as an FIR (Finite Impulse Response) filter, performs waveform equalization, and inputs the result to a maximum likelihood decoder (ML) 226.

The maximum likelihood decoder 226 is a Viterbi decoder, and performs known Viterbi decoding. The viterbi-decoded data string is RLL-demodulated by an RLL demodulator 227, then an error correction decoder 228 corrects the errors of this data string using error correction codes, and outputs the user data. The error correction decoder 228 is an ECC decoder, for example.

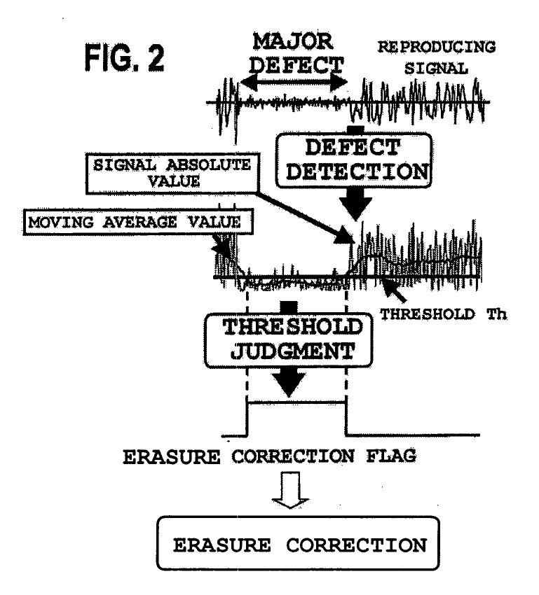

According to this embodiment, a medium defect detector 230 detects a defective section from a PR equalized series from the PR waveform equalization section 220, and generates a erasure symbol flag, as described in FIG. 2. Then an OR circuit 229 computes the OR of a previously detected symbol flag acquired from the TA detector 221 which detected thermal asperity and the erasure symbol flag, and outputs the result to the error correction decoder 228. The error correction decoder 228 specifies an error position according to the erasure symbol flag from the OR circuit 229 and corrects the errors, that is, corrects erasure.

Now the medium defect detector 230 will be described with reference to FIG. 2. A signal reflected at a center level of the PR equalized series (reproducing signal in FIG. 2) is generated (absolute signal if the center is “0”), and a moving average is computed for the absolute value of this signal for an L sampling length.

The moving average value, which is the moving average computing result, is sliced with the threshold Th to generate temporary erasure flags. In the generated temporary erasure flags, single and short flags are detected by the counter, and are eliminated. If a distance between two flags is short in the temporary erasure flags, these flags are combined into one flag. By this operation, erasure flags are generated.

The erasure flags are converted into erasure block flags corresponding to the restriction of the modulator 237. The erasure block flags are converted into erasure symbol flags (erasure correction flags) in the error correction symbol unit. The erasure symbol flags are output to the error correction decoder 228.

In this way, the moving average value of the reproducing signal is computed, and this moving average value is sliced with the threshold Th to detect a defect, so a continuous amplitude drop can be detected accurately compared with a simple threshold detection, deterioration of the error correction capacity, due to a detection error, can be suppressed, and in particular a medium defect section can be detected from the reproducing signal even if it is a multi-value PR reproducing signal.

Also a defect can be detected in the previous stage of the error correction decoding, so a defect can be corrected at an early stage, and by performing erasure error correction in an error correction decoder, the error correction capability can be made efficient, and data reliability can be improved. As a result, decoding speed improves. Also in a perpendicular magnetic recording system of which reproducing signals have a DC component, a medium defect can be detected, therefore the present invention can contribute to improving the decoding performance.

Also based on the sliced result, temporary erasure flags are generated, and isolated flags are removed, and flags close to each other are integrated to create erasure flags, so a short burst can be removed and detection errors can be suppressed. By regarding a continuous burst as one burst, the burst error detection performance can be improved.

### Second Embodiment of Recording/Reproducing Device

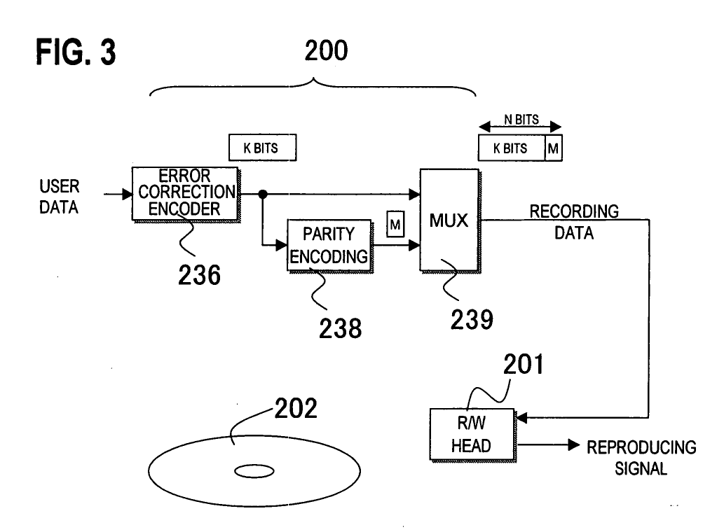

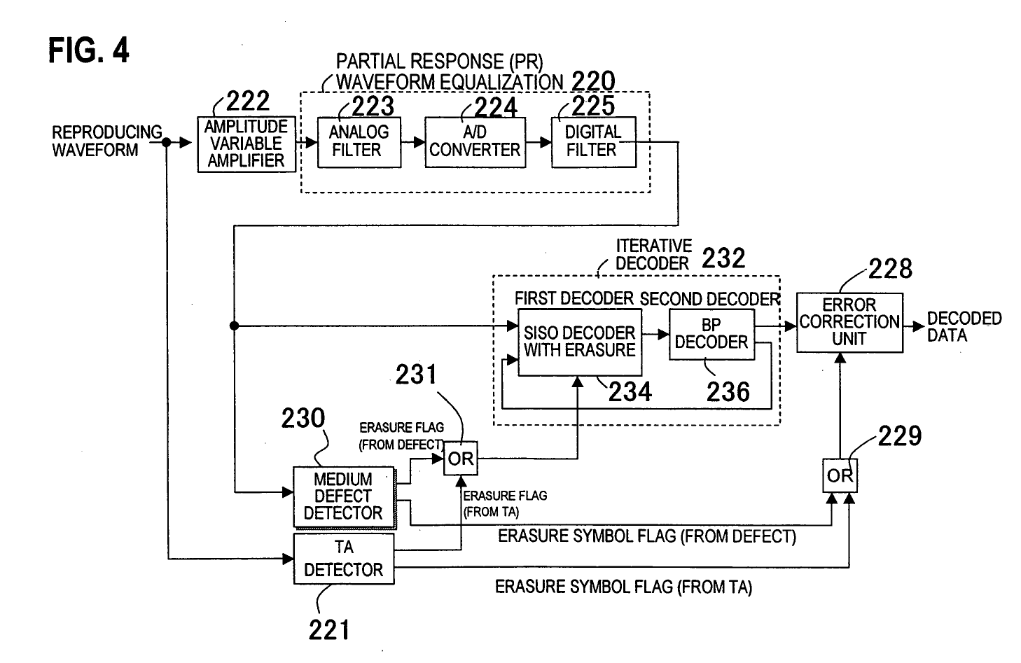

FIG. 3 and FIG. 4 are block diagrams depicting a second embodiment of the recording/reproducing device of the present invention. FIG. 3 and FIG. 4 shows a iterative decoding type recording/reproducing device of a magnetic disk device, where composing elements the same as FIG. 1 are denoted with the same reference symbols.

As the configuration of the recording system in FIG. 3 shows, an error correction code is created and added to user data in an error correction encoder 236. For the error correction encoder 236, an ECC (Error Correction Code) encoder, for example, is used.

Then a parity encoder 238 creates M bits of parity for K bits of output of the error correction encoder 236. For the parity encoder 238, an LDPC (Low Density Parity) encoder, SPC (Single Parity) encoder or turbo encoder, for example, can be used.

A multiplexer 239 adds M bits of parity bits to the K bits of the output of the error correction encoder 236, and creates a recording data string. Based on the recording data string, a preamplifier, which is not illustrated, generates the write current of a write head of a read/write head 201, drives the write head, and records the data on the magnetic disk 202.

For reproducing, a read head of the read/write head 201 reads the recorded data from the magnetic disk 202. As shown in FIG. 4, a reproducing waveform from the read head is input to a preamplifier, which is not illustrated. A thermal asperity detector 221 detects a thermal asperity from the reproducing waveform, as described in FIG. 16. If the thermal asperity is detected, the thermal asperity detector 221 outputs a erasure correction symbol flag for this portion.

A variable gain amplifier (VGA) 222 adjusts the amplitude of the reproducing waveform, and outputs it to a PR waveform equalization section 220. In the PR waveform equalization section 220, an analog (low pass) filter (LPF) 223 cuts a high frequency band of the reproducing signal of which amplitude has been adjusted, and an A/D converter (ADC) 224 converts the analog output thereof into digital signals. Then a digital filter 225, such as an FIR (Finite Impulse Response) filter, performs waveform equalization, and inputs the result to a iterative decoder 232.

The iterative decoder 232 is comprised of a soft-input soft-output (SISO) decoder 234 for a PR equalized series, and a belief propagation (BF) decoder 236 for low density parity check (LDPC) codes.

For the soft-input soft-output decoder 234, a BCJR (Bahl-Cocke-Jelinek-Raviv), MAP (Maximum A Posteriori) decoding or SOVA (Soft Output Viterbi Algorithm), for example, can be used.

For the belief propagation decoder 236, Sum-Product (SP) decoding or Min-Sum decoding, for example, is used. For the iterative decoding method, LDPC is used as an example, but decoding for turbo codes or single parity check (SPC) codes, for example, may be used.

A iteratively decoded data string is error-corrected by an error correction decoder 228 using error correction codes, and user data is output. The error correction decoder 228 is an ECC decoder, for example.

In the present embodiment, the medium defect detector 230 detects the defective section in the PR equalized series from the PR waveform equalization section 220, and generates erasure flags and erasure symbol flags, as described in FIG. 2. Then an OR circuit 231 computes the OR of the previously detected erasure flags acquired from the TA detector 221 and these erasure flags, and outputs the result to the SISO decoder 234.

The OR circuit 229 also computes the OR of the previously detected erasure symbol flags acquired from the TA detector 221 and these erasure symbol flags, and outputs the result to an error correction decoder 228. The error correction decoder 228 specifies an error position according to the erasure symbol flags from the OR circuit 229, just like FIG. 1, and corrects errors, that is, corrects erasure.

Then the SISO decoder 234 sets a branch metric calculation value to “0” or sets a soft output value (reliability information) to “0” at a position where a flag is ON according to the erasure flags generated by the medium defect detector 230 and the TA detector 221.

In the iterative decoder 232, reliability information for the recording data “0” or “1” is repeatedly propagated between this SISO decoder 234 and the BP decoder 236, and the BP decoder 236 and the SISO decoder 234 under predetermined conditions. After iteration is over, the reliability information is judged as “0” or “1”, and is input to the error correction decoder 228. The error correction decoder 228 corrects erasure according to the erasure symbol flags generated by the medium defect detector 230 and the TA detector 221, just like FIG. 1.

In this embodiment, as shown in FIG. 2, the medium defect detector 230 detects a defective section in the PR equalized series from the PR waveform equalization section 220, and generates the erasure flags and erasure symbol flags.

And the OR circuit 231 computes the OR of the previously detected erasure flags acquired from the TA detector 221 and these erasure flags, and corrects the erasure of the reliability information of the SISO decoder 234. Therefore in the iterative decoding stage, the medium defect is detected and the corresponding reliability information can be corrected, therefore the iterative decoding capability can be improved, and the reliability of the data can be improved.

The OR circuit 229 also computes the OR of the previously detected erasure symbol flags acquired from the TA detector 221 and these erasure symbol flags, and outputs the result to the error correction decoder 228. The error correction decoder 228 specifies the error position according to the erasure symbol flag from the OR circuit 229, and corrects the errors, that is, corrects the erasure.

Since the medium defect is detected and erasure errors are corrected by the error correction decoder 228, error correction capability can be made more efficient, and the reliability of data can be improved.

Medium Defect Detector

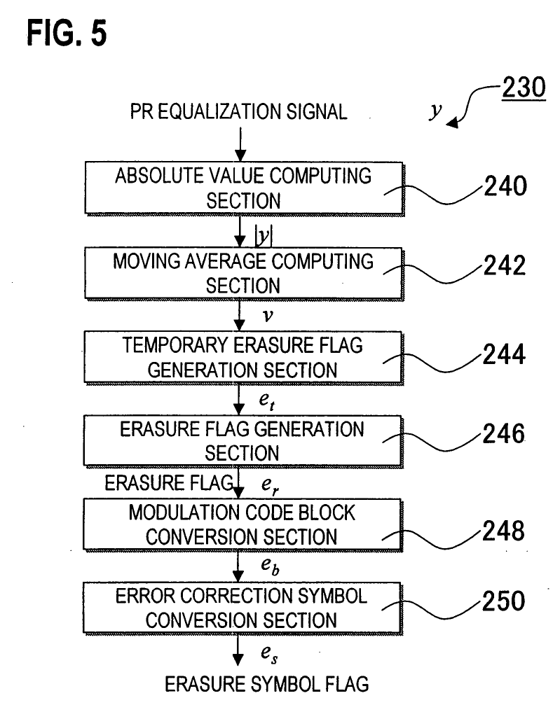

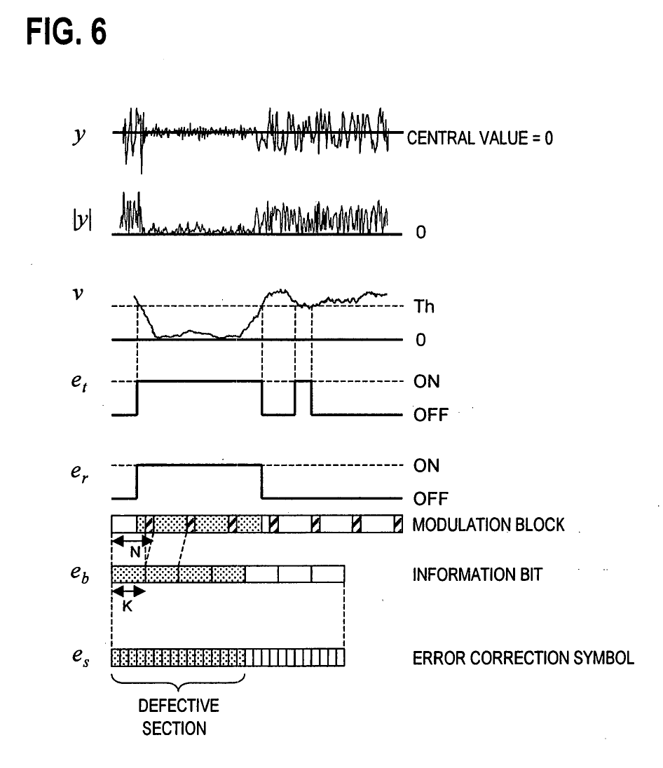

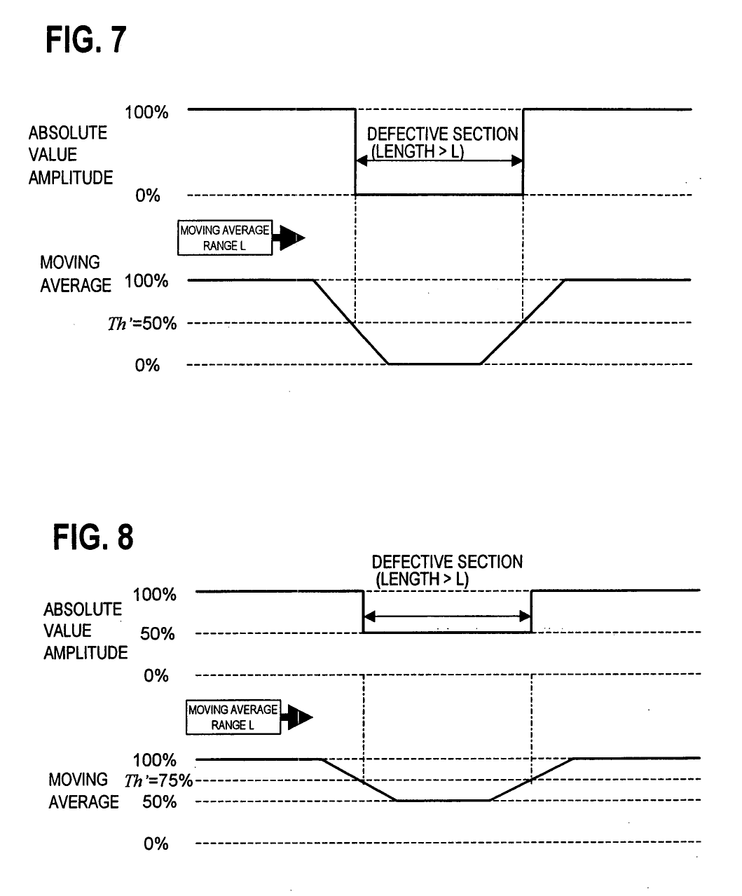

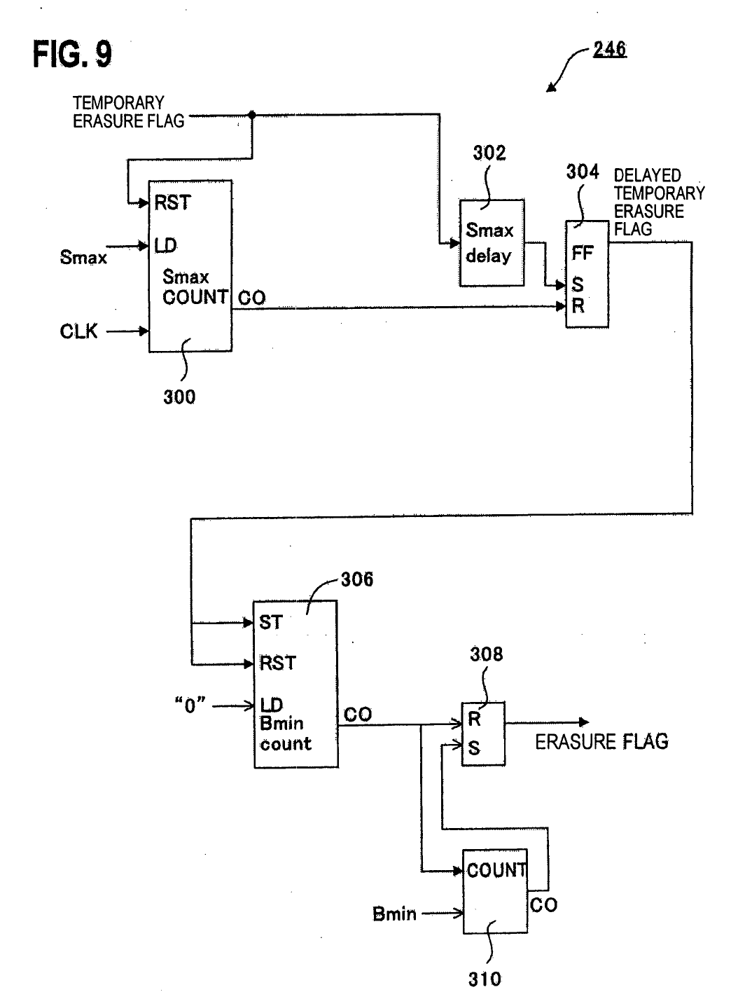

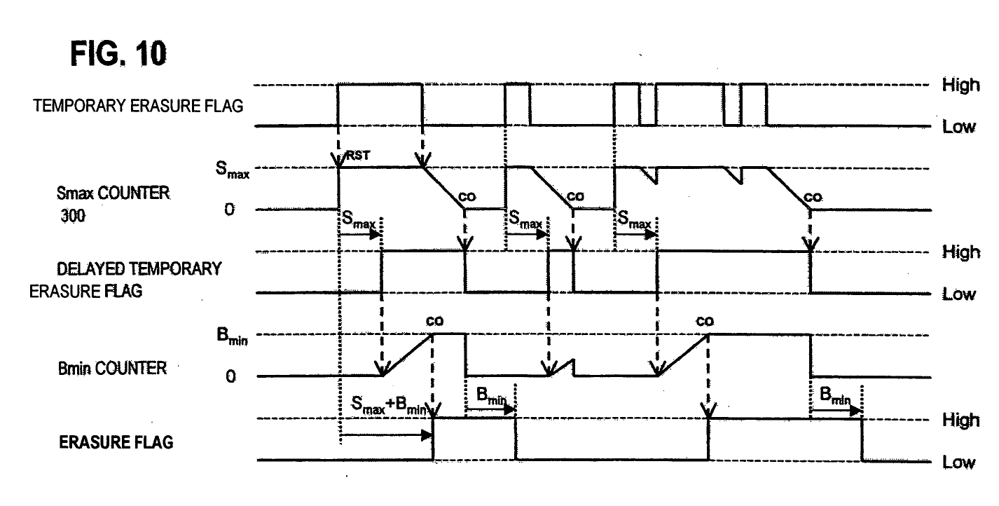

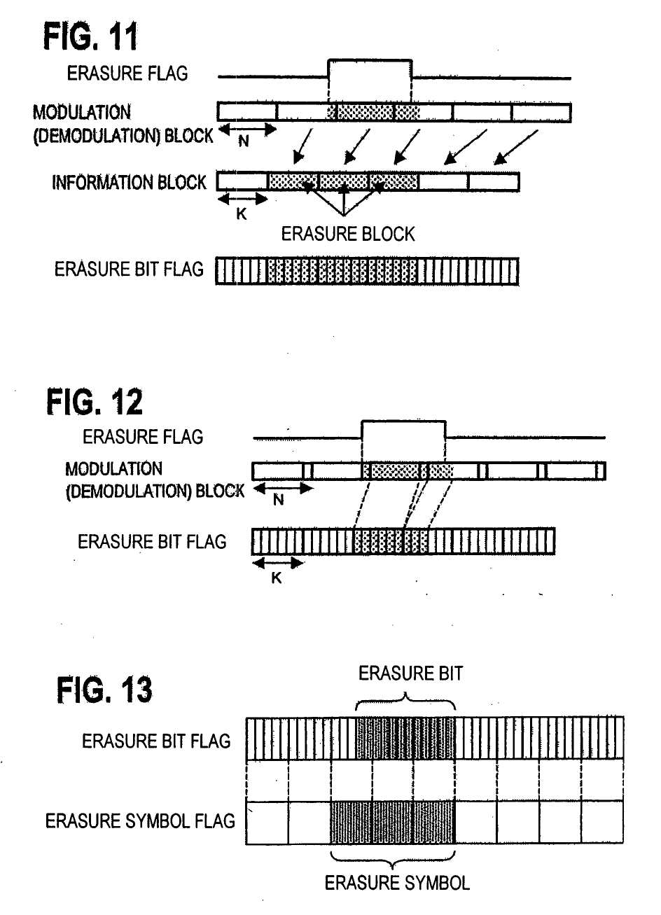

Now the configuration of the medium defect detector 230 in FIG. 1 to FIG. 4 will be described. FIG. 5 is a block diagram depicting the medium defect detector 230 in FIG. 1 to FIG. 4, FIG. 6 is a diagram depicting the operation of the signals of each section of the medium defect detector 230 in FIG. 5, FIG. 7 and FIG. 8 are diagrams depicting the threshold in FIG. 5 and FIG. 6, FIG. 9 is a block diagram depicting the erasure flag generation section in FIG. 5, FIG. 10 is a diagram depicting the operation of the configuration in FIG. 9, FIG. 11 and FIG. 12 are diagrams depicting the modulation code block conversion section in FIG. 5, and FIG. 13 is a diagram depicting the operation of the error correction symbol conversion section in FIG. 5.

As FIG. 5 shows, the medium defect detector 230 is comprised of an absolute value computing section 240, a moving average computing section 242, a temporary erasure flag generation section 244, a erasure flag generation section 246, a modulation code block conversion section 248 and an error correction symbol conversion section 250.

The absolute value computing section 240 sets the central value (average value) of the signal of the PR equalized series y to “0”, as shown in FIG. 6, and computes the absolute value |y| of the PR equalized series. In other words, the absolute value computing section 240 calculates the average value of the PR equalized series y, and then calculates the absolute value of the PR equalized series y with the average value as “0”.

The moving average computing section 242 computes the moving average of the range of the L samples for the absolute value |y| of the PR equalized series. The moving average value vk is calculated by the following Expression (1).

$$[ Expression 1 ] \\ {v}_{k} = \frac{1}{L} {\sum }_{n = - L / 2}^{+ L / 2} \vert {y}_{k + n} \vert \qquad ( 1 )$$

In other words, the moving average value vk in k samples is calculated by adding the absolute values |y| in the range of the L samples with the sampling point k at the center, and dividing the result by the range L. This range L is preferably a power of 2 in order to decrease the calculation volume in division. In other words, the division can be performed by bit shift.

In this case, L=2′, and m is greater than the PR restricted length (m>PR restricted length). This means that if m is the PR restricted length or less, the generation of all the patterns is not guaranteed, and therefore a detection error may occur.

Then the temporary erasure flag generation section 244 slices the moving average value v with an arbitrary threshold Th to perform threshold detection, as shown in FIG. 6, and generates the temporary erasure flag et. The threshold Th can be arbitrarily set, but it is desirable to be set as follows.

As FIG. 7 and FIG. 8 show, the threshold Th of the moving average value is determined to be a predetermined ratio value, as shown in the following Expression (2), using the average value |y|avg of the absolute values of the original signal amplitude.

[Expression 2]
Th=|y|_{avg}×Th′ (2)

For example, in order to detect 0% as a defective section in the absolute value of the amplitude, as FIG. 7 shows, Th′ in Expression (2) is set to 50% (=0.5) since the moving average has inclined portions. On the other hand, in order to detect 50% as a defective section in the absolute value of the amplitude, as FIG. 8 shows, Th′ in Expression (2) is set to 75% (=0.75).

In other words, if the absolute value of the amplitude exceeds 0% and is not more than 50%, Th′=0.75 should be used to detect the defective section. This value, however, is the case of an ideal value without noise, and this value must be corrected for actual use.

The length of equalizing the absolute value may be determined by a sequential computation similar to Expression (1), targeting the sampling period, that is sufficiently longer than the moving average range L, or it may be set in advance. To set the value in advance, the absolute value of the signal detection expected values in the SISO decoder 234, for example, may be set as an averaged value.

The erasure flag generation section 246 links continuous temporary erasure flags and removes the short temporary erasure flag to generate erasure flags. Here a maximum gap space for linking continuous temporary erasure flags is defined as Sₘₐₓ, and the minimum flag length for removing the short temporary erasure flag is defined as Bₘᵢₙ.

In the present embodiment, it is difficult to detect a defect of which length is less than (Bₘᵢₙ+L) because of a drop in amplitude due to a defect and the influence of noise. Therefore Bₘᵢₙ is determined based on the error correction capability of the internal encoding system (particularly the iterative decoding system). Sₘₐₓ, which compensates transient fluctuation due to the moving average operation, basically can be the same value as L.

FIG. 9 is a block diagram depicting the erasure flag generation section 246, and FIG. 10 is an operation time chart of FIG. 9. As FIG. 9 shows, the erasure flag generation section 246 is comprised of an Sₘₐₓ counter 300 for linking temporary erasure flags, a delay unit 302, a delay temporary erasure flag generation flip-flop 304, and a Bₘᵢₙ counter 306 for removing an isolated temporary erasure flag, a flip-flop 308 for generating a erasure flag, and a counter 310.

The operation in the configuration in FIG. 9 will be described with reference to FIG. 10. When the temporary flag is in High state (threshold in FIG. 6 or less), the Sₘₐₓ counter 300 is reset (RST), and the initial value Sₘₐₓ is loaded. When the temporary erasure flag is Low (threshold in FIG. 6 or more), the Sₘₐₓ counter 300 decrements from the load value Sₘₐₓ, and generates a carry out (CO) pulse when the count value becomes “0”.

The delay circuit 302 delays the temporary erasure flag by time Sₘₐₓ. The flip-flop 304 is set by the rise of the output of the delay circuit 302 (rise of signal resulting when the temporary erasure flag is delayed), and is reset by the CO pulse of the counter 300, and generates the delay temporary erasure flag in FIG. 10.

In other words, the space between adjacent temporary erasure flags is monitored by the Sₘₐₓ counter 300, and temporary erasure flags, of which space is Sₘₐₓ or less, are integrated.

Then the Bₘᵢₙ counter 306, triggered by the rise of the delay temporary erasure flag, starts counting up, and when the count value becomes Bₘᵢₙ, a carry out (CO) pulse is generated, and the Bₘᵢₙ counter is reset when the temporary erasure flag is Low, and the initial value “0” is loaded.

The flip-flop 308 is set by the CO pulse of the counter 306. The counter 310 starts counting at the fall of the CO pulse of the counter 306, and outputs the carry out (CO) pulse when the count value reaches Bin. The flip-flop 308 is reset by the CO pulse of the counter 310. Therefore, as FIG. 10 shows, the flip-flop 308 generates a erasure flag which rises by the CO pulse of the counter 306, and becomes Low at a position which is delayed by Bₘᵢₙ from the fall of the CO pulse. In other words, a temporary erasure flag, of which flag length is Bₘᵢₙ or less, is removed.

The modulation code block conversion section 248 converts the erasure flags so that the erasure flags correspond to the modulated and encoded data. For the modulation encoding, run length limited (RLL) modulation or parity encoding is used after error correction encoding is performed, so that K bits of data is converted into N bits of modulation blocks for each K bits of data after error correction encoding is performed (see FIG. 1 and FIG. 3).

The modulation code block conversion section 248 associates the N bits of modulation blocks with the range of the erasure flag, and converts the erasure flags into the K bits of the erasure bit flag. The operation of the modulation code block conversion section is different depending on the method of modulation encoding.

FIG. 11 shows the modulation code block conversion rule for unsystematic codes, such as RLL modulation. An unsystematic code is a code for converting the K bits of data into N bits of modulation data according to the modulation rule, as shown in FIG. 1. At demodulation, each N bits of a modulation block is RLL-demodulated and becomes K bits of an information block.

At this time, the modulation code block conversion section 248 regards all the bits of the information block as erasure at information block conversion if any erasure flag is included in the modulation block.

FIG. 12 shows the modulation code block conversion rule for a systematic code, such as parity code. As shown in FIG. 3, a systematic code is a code for converting K bits of data into N bits of modulation data by merely adding M bits of information.

At decoding, M bits of parity information is checked, and the block is demodulated only by deleting the M bits of data. At this time, as FIG. 12 shows, the modulation code block conversion section 248 converts the erasure flag merely by deleting the M bits of the parity section in the modulation block.

Then the error correction symbol conversion section 250 converts the erasure bit flag, which was converted into bit units, demodulated by the modulation code block conversion section 248, into error correction symbol units. In other words, the error correction decoder 228 corrects an error in symbol units (e.g. 5 bits), so the erasure flag bits are converted into symbol units so as to conform to this error correction rule. As FIG. 13 shows, if at least 1 bit of erasure bit is included in the symbol, the entire symbol is handled as a erasure symbol.

By the above operation, the erasure symbol flag is generated, and the erasure error is corrected by the error correction code according to the erasure symbol flag.

Since the moving average is detected by a threshold, a continuous amplitude drop can be detected accurately compared with a simple threshold detection, and a deterioration of error correction capability due to a detection error can be suppressed. Also a detection error can be suppressed by removing short bursts. Moreover by regarding continuous bursts as one burst, the detection of a burst error can be improved.

### Other Embodiments

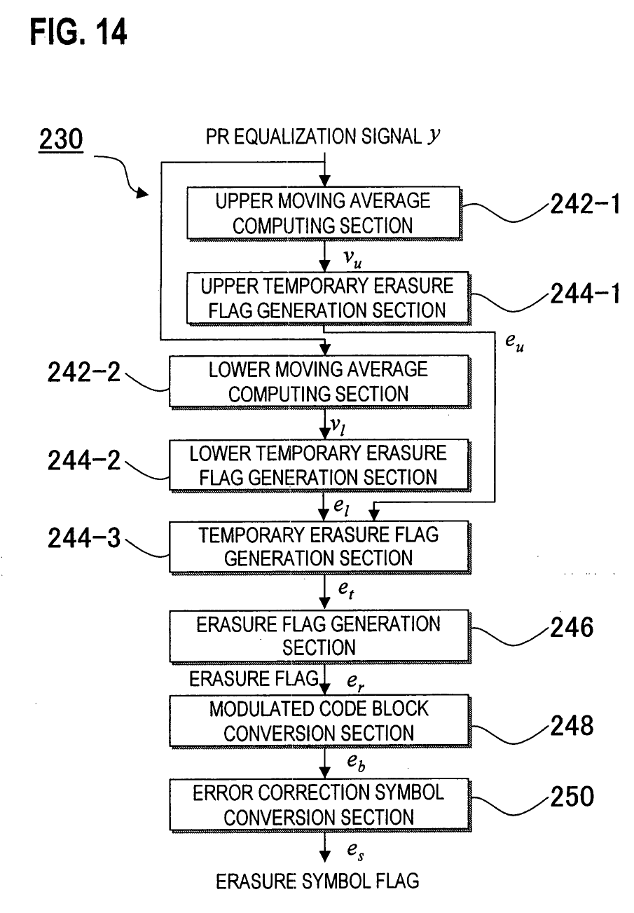

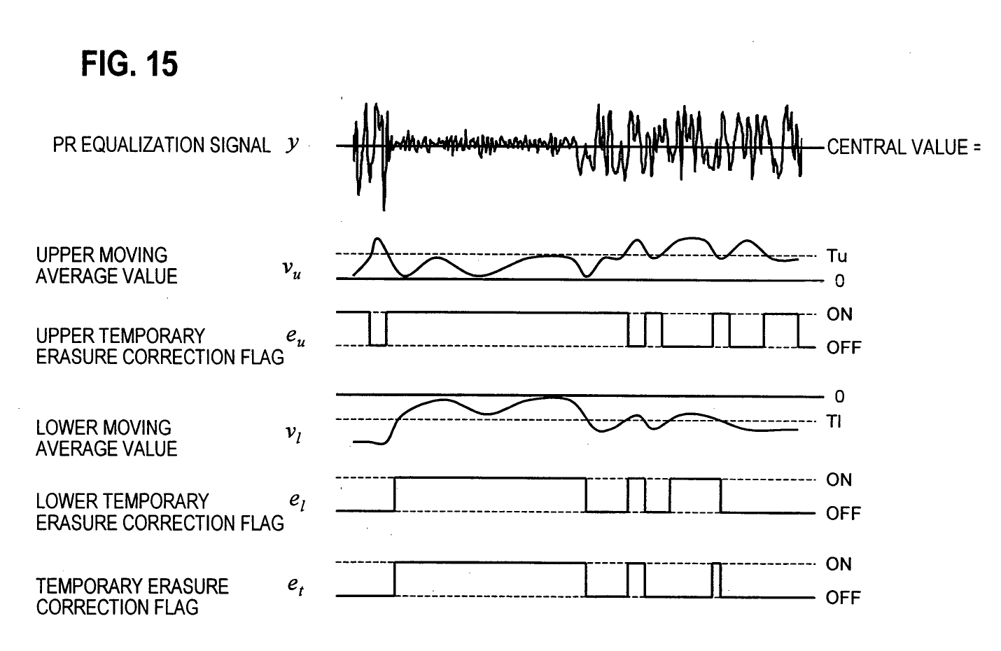

FIG. 14 is a block diagram depicting another embodiment of the medium defect detector of the present invention, and FIG. 15 is a diagram depicting the signals in FIG. 14. The other embodiment in FIG. 14 and FIG. 15 is a variant form of a temporary erasure flag generation method according to the embodiment in FIG. 5. If the asymmetry of the signal amplitude is conspicuous because of the characteristics of the magnetic head, good defect detection becomes possible by using this embodiment.

In FIG. 14, composing elements the same as FIG. 5 are denoted with the same reference symbols. The medium defect detector 230 is comprised of an upper moving average computing section 242-1, an upper temporary erasure flag generation section 244-1, a lower moving average computing section 242-2, a lower temporary erasure flag generation section 244-2, a temporary erasure flag generation section 244-3, a erasure flag generation section 246, a modulation code block conversion section 248, and an error correction symbol conversion section 250.

The upper and lower moving average computing sections 242-1 and 242-2 compute the moving average of the PR equalized string y in the respective range of the L samples for the upper side and lower side of the PR equalized series with the DC level of the signal as the center (central value “0” in FIG. 15). “0” is added at the upper side or lower side if the signal level is the same as the signal level of the opposite side. The upper moving average value vuk and lower moving average value vlk are calculated by the following Expressions (3) and (4).

$$\begin{matrix}[ Expression 3 ] \\ {v}_{k}^{u} = \frac{1}{L / 2} {\sum }_{n = - L / 2}^{+ L / 2} {y}_{k + n}^{u} & ( 3 ) \\ [ Expression 4 ] \\ {v}_{k}^{l} = \frac{1}{L / 2} {\sum }_{n = - L / 2}^{+ L / 2} {y}_{k + n}^{l} & ( 4 )\end{matrix}$$

In other words, the upper and lower moving average values vuk and vlk of the k samples are calculated by adding the upper and lower signals y in the range of the L samples with the sampling point k at the center, and dividing the result by the range L/2. The range L is preferably a power of 2 in order to decrease the calculation volume in division. In other words, division can be performed by bit shift.

In this case, L=2^{m}, and m is greater than the PR restricted length (m>PR restricted length). This means that if m is the PR restricted length or less, the generation of all the patterns is not guaranteed, and therefore a detection error may occur.

Then the upper and lower temporary erasure flag generation sections 244-1 and 244-2 slice the upper moving average value vu and lower moving average value v1 with the respective thresholds Tu and Tl, and generate the upper temporary erasure flag eu and lower temporary erasure flag el, as shown in FIG. 15. The flag generation expressions are shown by the following Expressions (5) and (6).

$$\begin{matrix}[ Expression 5 ] \\ {e}_{k}^{u} = \{ \begin{matrix}ON , & {v}_{k}^{u} \leq Tu \\ OFF , & {v}_{k}^{u} > Tu\end{matrix} & ( 5 ) \\ [ Expression 6 ] \\ {e}_{k}^{l} = \{ \begin{matrix}ON , & {v}_{k}^{l} \leq Tl \\ OFF , & {v}_{k}^{l} > Tl\end{matrix} & ( 6 )\end{matrix}$$

The thresholds Tu and tl can be freely set, but preferably should be a predetermined ratio of the average value of the signal amplitudes respectively just like the case of Expression (2).

Then the temporary erasure flag generation section 244-3 computes the AND of the upper temporary erasure flag and the lower temporary erasure flag to generate the temporary erasure flag ‘et’. This is expressed by the following Expression (7).

[Expression 7]
eₖ^{t}=eₖ^{u}eₖ^{l} (7)

The configuration and operation of the erasure flag generation section 246, modulation code block conversion section 248 and error correction symbol conversion section 250 are the same as the embodiment shown in FIG. 5.

In this way, the moving average is computed separately for the upper side and lower side of the PR equalized series with the DC component at the center, and defects are detected using the respective threshold, therefore defects can be detected effectively for asymmetric signals.

In the above embodiments, the unsystematic code was described using RLL, but other unsystematic codes can be used, and systematic code was described using LDPC, but other systematic codes, such as turbo code, can be used. An example of applying the present invention to the recording/reproducing device of a magnetic disk device was described, but the present invention can also be applied to other medium storage devices, such as an optical disk device and tape device.

The present invention was described using embodiments, but the present invention can be modified in various ways within the scope of the essential character thereof, and these variant forms shall not be excluded from the scope of the present invention.

Since the moving average value of the reproducing signal is computed, and this moving average value is sliced with a threshold Th to detect a defect, a continuous amplitude drop can be detected accurately compared with a simple threshold detection, deterioration of error correction capability due to a detection error can be suppressed, and in particular a medium defect section can be detected from the reproducing signal even if it is a multi-value PR reproducing signal. Also a defect can be detected in the previous stage of the error correction decoding, so a defect can be detected at an early stage, and erasure can be corrected at an early stage during error correction. Therefore decoding speed improves. Even in a perpendicular magnetic recording system of which reproducing signals have a DC component, a medium defect can be detected, therefore the present invention can contribute to improving the decoding performance.

What is claimed is:

1. A medium defect detector for detecting a medium defect position from information recorded on a medium and reflecting the detection result into a erasure error correction of the information, comprising:
a moving average computing section for computing a moving average of an equalization signal read from a medium in a predetermined range for upper and lower equalization signals of which center is a central value of the signal amplitude;
a erasure position detection section for detecting an amplitude drop position by comparing the moving average computing result and a predetermined threshold; and
a conversion section for converting the detected erasure position into a signal to be reflected to the erasure error correction of the information.

2. The medium defect detector according to claim 1, wherein the erasure position detection section comprises:
a temporary erasure flag generation section for comparing the moving average computing result and a predetermined threshold and generating temporary erasure flags; and
a erasure flag generation section for integrating and deleting the temporary erasure flags based on a space and a width of the temporary erasure flags so as to generate erasure flags,
and wherein the conversion section comprises an error correction symbol conversion section for converting the erasure flag into a symbol of a correction unit of the error correction.

3. The medium defect detector according to claim 1, wherein the moving average computing section comprises:
an absolute value computing section for computing an absolute value acquired by reflecting the equalization signal with the central value of the signal amplitude as a center; and
a moving average computing section for computing a moving average in a predetermined range for the computed absolute value.

4. The medium defect detector according to claim 1, wherein the moving average computing section separates the equalization signal into an upper equalization signal and a lower equalization signal with the central value of the signal amplitude as a center, computes a moving average in a predetermined range for the upper equalization signal and lower equalization signal respectively, and creates an upper moving average signal and a lower moving average signal,
and wherein the erasure position detection section compares the upper moving average signal and lower moving average signal with a predetermined upper threshold and a lower threshold, and detects the amplitude drop position.

5. The medium defect detector according to claim 2, wherein the erasure flag generation section generates a erasure flag by integrating the temporary erasure flags based on a space of the temporary erasure flags, and deleting the temporary erasure flags based on a width of the temporary erasure flags.

6. The medium defect detector according to claim 1, wherein the equalization signal is a PR (Partial Response) equalization signal.

7. The medium defect detector according to claim 1, wherein the conversion section further comprises:
a block conversion section for converting the detected erasure position into an information block of a modulation block of the reproducing signal; and
a symbol conversion section for converting the converted erasure position into a symbol unit to be reflected to the erasure error correction.

8. The medium defect detector according to claim 7, wherein when the reproducing signal is an unsystematic code modulation signal, the block conversion section converts the detected erasure position into an information block unit of the modulation block of the reproducing signal.

9. The medium defect detector according to claim 7, wherein the block conversion section associates the detected position with each bit of the information block of the modulation block of the reproducing signal when the reproducing signal is a systematic code modulation signal.

10. The medium defect detector according to claim 1, wherein the threshold is determined from an average value of amplitudes of the equalization signal.

11. An information reproducing device for reproducing information recorded on a medium, comprising:
an equalizer/decoder for waveform-equalizing and decoding a signal reproduced from the medium;
an error correction circuit for correcting an error of the decoded data;
a moving average computing section for computing a moving average of an equalization signal of the reproduced signal in a predetermined range for upper and lower equalization signals of which center is a central value of the signal amplitude;
a erasure position detection section for detecting an amplitude drop position by comparing the moving average computing result and a predetermined threshold; and
a conversion section for converting the detected erasure position into a signal to be reflected to the erasure error correction of the error correction circuit.

12. The information reproducing device according to claim 11, wherein the erasure position detection section comprises:
a temporary erasure flag generation section for comparing the moving average computing result and a predetermined threshold and generating temporary erasure flags; and
a erasure flag generation section for integrating and deleting the temporary erasure flags based on a space and a width of the temporary erasure flags so as to generate a erasure flag,
and wherein the conversion section comprises an error correction symbol conversion section for converting the erasure flag into a symbol of a correction unit of the error correction.

13. The information reproducing device according to claim 11, wherein the moving average computing section further comprises:
an absolute value computing section for computing an absolute value acquired by reflecting the equalization signal with the central value of the signal amplitude as a center; and
a moving average computing section for computing a moving average in a predetermined range for the computed absolute value.

14. The information reproducing device according to claim 11, wherein the moving average computing section separates the equalization signal into an upper equalization signal and a lower equalization signal with the central value of the signal amplitude as a center, computes a moving average in a predetermined range for the upper equalization signal and lower equalization signal respectively, and creates an upper moving average signal and a lower moving average signal,
and wherein the erasure position detection section compares the upper moving average signal and lower moving average signal with a predetermined upper threshold and a lower threshold, and detects the amplitude drop position.

15. The information reproducing device according to claim 12, wherein the erasure flag generation section generates a erasure flag by integrating the temporary erasure flags based on a space of the temporary erasure flags, and deletes the temporary erasure flags based on a width of the temporary erasure flags.

16. The information reproducing device according to claim 11, wherein the equalization signal is a PR (Partial Response) equalization signal.

17. The information reproducing device according to claim 11, wherein the conversion section further comprises:
a block conversion section for converting the detected erasure position into an information block of a modulation block of the reproducing signal; and
a symbol conversion section for converting the converted erasure position into a symbol unit to be reflected to the erasure error correction.

18. The information reproducing device according to claim 17, wherein when the reproducing signal is an unsystematic code modulation signal, the block conversion section converts the detected erasure position into an information block unit of the modulation block of the reproducing signal.

19. The information reproducing device according to claim 17, wherein the block conversion section associates the detected erasure position with each bit of the information block of the modulation block of the reproducing signal when the reproducing signal is a systematic code modulation signal.

20. The information reproducing device according to claim 11, wherein the threshold is determined from an average value of amplitudes of the equalization signal.
